(19) United States
(12) Patent Application Publication
(10) Pub. No.: US 2015/0361580 A1
(43) Pub. Date: Dec. 17, 2015

(54) DEVICE AND METHOD FOR PRODUCING MULTI SILICON CARBIDE CRYSTALS

(71) Applicant: USI OPTRONICS CORPORATION, Taipei (TW)

(72) Inventors: Chun-Hui HUANG, Taipei (TW); Tai-Huang LIN, Taipei (TW); Ching-Kun MAI, Taipei (TW)

(21) Appl. No.: 14/584,695

(22) Filed: Dec. 29, 2014

(30) Foreign Application Priority Data
Jun. 16, 2014 (TW) 103120739

(51) Int. Cl. C30B 23/02; C30B 29/36

(52) U.S. Cl. CPC C30B 23/02; C30B 29/36

(57) ABSTRACT

The present invention provides a device and method of use the device for simultaneously producing multiple silicon carbide crystals. The device comprises: a reaction unit comprising a cylindrical crucible and a circular cover corresponding to the cylindrical crucible; a thermal insulation material arranged above, below, and peripherally around the reaction unit; a reaction enclosure surrounding the reaction unit and the thermal insulation material; and a heating system corresponding to and encircling the reaction enclosure; wherein the cylindrical crucible has a side provided with a rotating mechanism for driving the cylindrical crucible into rotation, and the thermal insulation material above the reaction unit is arranged on the circular cover and has a thickness decreasing from a center of the circular cover toward a rim of the circular cover.

### BACKGROUND OF THE INVENTION

1. Technical Field

The present invention relates to a device and method for producing silicon carbide crystals, especially to a device and method for producing multi silicon carbide crystals.

2. Description of Related Art

Silicon carbide (SiC) has extremely high hardness second only to diamond and has a thermal conductivity (500 W/m·K) higher than not only those of silicon (Si) (150 W/m·K) and gallium arsenide (GaAs) (50 W/m·K), but also that of any metal at room temperature, which explains why a silicon carbide device can dissipate heat very efficiently even when working in a high-power environment. In addition, a comparison between the properties of 4H silicon carbide and the conventional electronic materials such as silicon, gallium arsenide, and gallium nitride (GaN) reveals that the energy gap of silicon carbide at 300K (2.40-3.25 eV) is larger than those of silicon (1.12 eV) and gallium arsenide (1.42 eV), and because of that, an electronic device made of silicon carbide can work under extremely high temperature without being influenced by the inherent conduction effect. With regard to breakdown voltage, silicon carbide can withstand eight times as great a voltage gradient as can silicon and gallium arsenide and is therefore applicable to high-voltage devices. Silicon carbide can also function under high frequencies (e.g., radio frequency (RF) and microwave frequency) due to its relatively high saturated electron drift velocity.

In view of the excellent material properties of silicon carbide, the development of monocrystalline silicon carbide growing techniques and of the manufacturing processes of silicon carbide devices started as early as 20 years ago. Since then, the supply chain of the silicon carbide industry—from the upstream monocrystalline material to device manufacture and product application—has been a subject of international research and development efforts. But why does such an outstanding material have yet to replace the traditional semiconductor materials? The reason lies in the fact that growing silicon carbide single crystals is the most difficult phase in the entire manufacturing process of silicon carbide devices, so difficult that the supply of silicon carbide wafer materials is still far short of demand today.

Methods for growing monocrystalline silicon carbide abound as a result of the development endeavors in the past two decades. The following methods, for example, can be used to grow silicon carbide single crystals. 1. High-temperature chemical vapor deposition (HTCVD): A gas containing the raw materials of carbon and silicon is transported to a chamber where the vapor of the materials grows silicon carbide single crystals directly on the silicon carbide seed crystal in the chamber. In the growing process, temperature and the ratio between the constituent materials affect not only the speed of crystal growth, but also the form of the crystal grown. Only those crystals growing at an appropriate speed are monocrystalline. Those growing too fast at a low temperature or under a high partial pressure tend to be polycrystalline. When the temperature is high or when a partial pressure is low, crystals are corroded faster than deposition and consequently shrink instead of grow, 2. Liquid-phase epitaxy (LPE): The driving force of the LPE method is molten silicon liquid with carbon dissolved therein. By cooling the molten silicon liquid gradually, the solubility of the dissolved carbon is lowered. As a result, nucleation and growth of silicon carbide takes place at the seed crystal. One of the difficulties in the development of LPE is the low solubility of carbon in silicon. To increase the solubility of carbon, it is necessary to add a rare-earth element or transition metal (e.g., Pr, Tb, Sc, etc.) as a medium, but the additional element raises purity issues in the final product. 3. Sublimation method: The sublimation method, also known as the physical vapor transport (PVT) method, is the most mature technique for growing silicon carbide crystals and, because of the low defect level of crystals formed in a sublimation system, is also the major mass production method for commercial use. In a typical silicon carbide growing process using this method, silicon carbide powder is heated to the sublimation temperature (i.e., 2200˜2500° C.) by induction coils until sublimed. The silicon carbide vapor is then guided to the seed crystal by creating a temperature gradient in the reaction crucible. As the gaseous silicon carbide slowly deposits on the relatively cool portion of the seed crystal, a single crystal is grown.

Referring to FIG. 1 for a schematic sectional view of the sublimation system disclosed in U.S. Pat. No. 4,866,005 (Re 34,861), the crucible 1 for use in a typical sublimation-based silicon carbide growing technique is made of graphite, and heating is carried out by a plurality of induction coils 2 until sublimation occurs. When the applied current runs through the coils, the crucible is heated. The source powder for crystal growth is silicon carbide 3, and the seed crystal 4 is also silicon carbide. The seed crystal is usually placed at the top of the interior of the crucible while the source powder for crystal growth is put inside the crucible, typically at a lower end thereof, facing the seed crystal once the crucible is heated, the desired controllable temperature gradient is created in the crucible by proper arrangement of the coils and the insulator. The temperature gradient causes the vapor of the source powder to condense on the seed crystal and thus form a single crystal 5. It can be known from the prior art that only one single crystal can be grown at a time.

### BRIEF SUMMARY OF THE INVENTION

The present invention provides a device for simultaneously producing multiple silicon carbide single crystals in order to overcome the drawback of the prior art that, when the sublimation method is used, only one crystal of silicon carbide can be prepared in a crucible at a time, which results in a relatively low yield at a relatively high cost.

Therefore, the present invention provide a device for producing multiple silicon carbide crystals, comprising: a reaction unit comprising a cylindrical crucible and a circular cover corresponding to the cylindrical crucible; a thermal insulation material arranged above, below, and peripherally around the reaction unit; a reaction enclosure surrounding the reaction unit and the thermal insulation material; and a heating system corresponding to and encircling the reaction enclosure; wherein the cylindrical crucible has a side provided with a rotating mechanism for driving the cylindrical crucible into rotation, and the thermal insulation material above the reaction unit is arranged on the circular cover and has a thickness decreasing from a center of the circular cover toward a rim of the circular cover.

Preferably, the circular cover is fixedly provided with a plurality of silicon carbide seed crystals each having a diameter ranging from 2 to 8 inches.

Preferably, the cylindrical crucible and the circular cover are made of a material selected from the group consisting of graphite and tantalum.

Preferably, the thermal insulation material is carbon fiber.

Preferably, the heating system is a radio-frequency heater or a resistance heater and is configured to heat the reaction unit to 1900° C.˜2500° C.

Preferably, the device further comprises one or a plurality of thermometers provided above the reaction unit.

Preferably, the silicon carbide seed crystals have a crystal structure. of a 3C, 4H, 6H, 211, or 15R polytype.

Preferably, the reaction enclosure remains a vacuum and is a quartz tube.

Preferably, the reaction enclosure further comprises a mass flow controller therein.

Another aspect of the invention is to provide a method for simultaneously producing multiple silicon carbide single crystals with the device of the present invention, comprising the steps of: (i) arranging a plurality of silicon carbide seed crystals on the circular cover of the reaction unit, and filling the corresponding cylindrical crucible with a sufficient amount of silicon carbide powder for crystal growth to a predetermined height; (ii) placing the reaction unit into the reaction enclosure, and extracting air from within the reaction enclosure, in which the reaction unit is placed, so as to maintain a predetermined pressure in the reaction enclosure; and (iii) heating the reaction unit to 1900° C.˜2500° C. with the heating system such that the silicon carbide powder sublimes and grows multiple silicon carbide single crystals on the silicon carbide seed crystals respectively.

The device of the present invention is so configured that a rotating mechanism is provided at a side of a cylindrical crucible to rotate the crucible, and that the thermal insulation material arranged on a circular cover is thinner toward the rim of the cover, allowing the creation of a uniform temperature field inside the reaction unit when the reaction unit is heated by a heating system. Thus, the plural seed crystals in the crucible will be heated evenly and grow silicon carbide single crystals concurrently to overcome the prior art drawback that only one crystal can be grown in a reaction unit at a time. The device therefore has a higher yield and features lower production costs than its conventional counterparts.

### BRIEF DESCRIPTION OF THE SEVERAL VIEWS OF THE DRAWINGS

FIG. 1 is a schematic drawing based on the disclosure of a prior art;

FIG. 2 schematically shows how seed crystals are arranged on the circular cover of the device of the present invention;

FIG. 3 schematically shows how the device of the present invention operates;

FIG. 4 schematically shows how the plural pieces of thermal insulation material on the circular cover of the device of the present invention are arranged; and

FIG. 5 schematically shows temperature distribution between, and over each of, the 2-inch seed crystals on the circular cover of the device of the present invention.

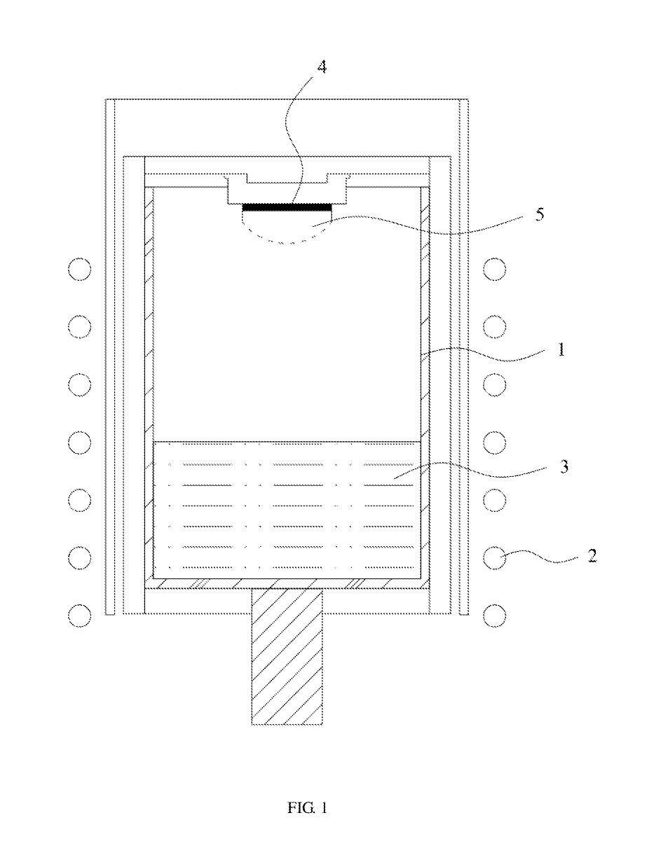

### DETAILED DESCRIPTION OF THE INVENTION

A detailed description is given below, with reference to the accompanying drawing, of how mass production of silicon carbide single crystals is achieved in some embodiments of the present invention by way of multiple silicon carbide single crystals. Please note that the same elements in the drawings are indicated by the same reference numerals and will not be described repeatedly. The embodiments and the drawings are provided only to demonstrate an approach to attaining the foresaid objective of the present invention and are not intended to be restrictive of the present invention.

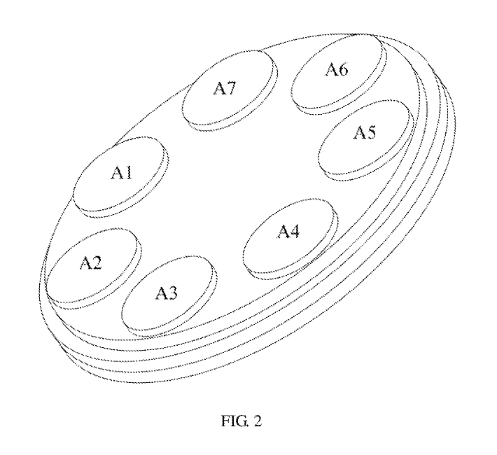

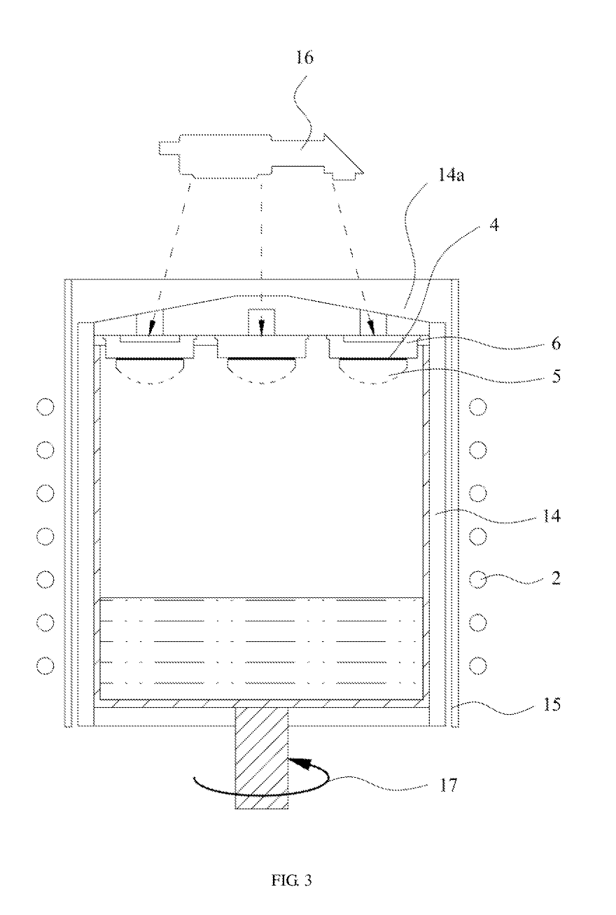

Referring to FIG. 2 and FIG. 3, the device according to an embodiment of the present invention includes a reaction unit for accommodating both seed crystals and silicon carbide powder. More specifically, the reaction unit has a circular cover 6 on which a plurality of seed crystals 4 can be arranged and fixed, and the reaction unit further includes a cylindrical crucible 1. The cylindrical crucible 1 can be made of any material, provided that the resultant crucible is resistant to high temperature, sturdy, and not prone to changes under high temperature. Preferably, the cylindrical crucible 1 is made of graphite or tantalum, especially the former, with a view to precluding any reaction between the cylindrical crucible 1 and the materials used for growing crystals, for crystal growth not only requires high-quality seed crystals and pure raw materials, but also requires the crucible and the thermal insulation material to contain as few impurities as possible. Graphite is also preferred because: (a) it is high-temperature resistant and has special thermal properties; (b) it does not soften but is increased in strength at ultra-high temperature; (c) its coefficient of thermal expansion is very small; (d) it has excellent electrical conductivity and thermal conductivity; and (e) it is almost thermally insulating at extremely high temperature.

The reaction unit can be completely sealed. The seed crystals 4 (or A1˜A7 in FIG. 2) are arranged on the circular cover 6 above the cylindrical crucible 1. Silicon carbide powder 3 is placed on the inner bottom of the cylindrical crucible 1. The seed crystals have a diameter ranging from 2 to 8 inches, and the crystal structure of the silicon carbide seed crystals can be any of the 3C, 4H, 6H, 2H, and 15R polytypes.

In this embodiment, the device of the present invention is further provided with a thermal insulation material 14 above, below, and peripherally around the reaction unit. To keep the cylindrical crucible 1 in a high-temperature state, the thermal insulation material 14 used in this embodiment is one capable of resisting high temperature, preferably made of the element carbon, and more preferably made of carbon fibers.

The device in this embodiment further includes a reaction enclosure 15 surrounding the reaction unit and the thermal insulation material 14 and configured for receiving the reaction unit. After the reaction unit is put into the reaction enclosure 15, air is extracted from within the reaction enclosure 15 to create a vacuum therein, and an inert gas can be introduced into the reaction enclosure 15 if necessary. The pressure in the reaction enclosure is kept at an appropriate level during crystal production. The reaction enclosure 15 is preferably made of quartz.

The device in this embodiment further includes a heating system corresponding to and encircling the reaction enclosure 15. The heating system can be configured to perform heating by radio-frequency (RF) coils or by resistors. In this embodiment, induction coils 2 are used, which are arranged outside the thermal insulation material 14 and encircle the reaction enclosure 15 so as to heat the cylindrical crucible 1 therein to about 1900° C.˜2500° C.

The present invention is characterized in that uniform heating of the reaction unit can be achieved with the assistance of a rotating mechanism 17 of the device and through dimensional variation of the thermal insulation material 14 arranged above the reaction unit, and that the temperature field between the seed crystals is rendered uniform by varying the thickness of the thermal insulation material 14 arranged above the circular cover 6, or more particularly by reducing the thickness of the thermal insulation material 14 from the center of the cover toward the rim of the cover. These characteristic features will be described in detail below with reference to the accompanying drawings.

In addition, one or a plurality of thermometers 16 (e.g., infrared thermometers) can be provided above the reaction unit of the device in order to measure the temperature of each seed crystal (4, A1˜A7) with precision. The silicon carbide powder on the inner bottom of the cylindrical crucible 1 is sublimed by heating and slowly deposits on the relatively cool portions of the seed crystals (4, A1˜A7) in the presence of a temperature gradient such that silicon carbide single crystals are formed.

In this embodiment, referring to FIG. 2, there are a total of seven 2-inch silicon carbide seed crystals (4, A1˜A7) arranged on the circular cover 6. The circular cover 6 is made of high-purity graphite and is so configured that the seed crystals (4, A1˜A7) can be arranged thereon. More specifically, the seed crystals (4, A1˜A7) are fixedly bonded to the cover by an adhesive. As shown in FIG. 2, the seven seed crystals are designated by A1˜A7 counterclockwise. During the crystal growing process, crystal growth continues in the same direction (e.g., on the C-plane {0001}), and each crystal expands little by little in the A-axis direction. As mentioned previously, high-quality silicon carbide seed crystals should be used, and the seed crystals used in this embodiment have a micropipe density less than 10 cm⁻².

Referring to FIG. 3, high-purity silicon carbide powder 3 corresponding to the crystals to be grown is filled into the cylindrical crucible 1 and is located opposite the seed crystals 4. The silicon carbide powder used in this embodiment is of 4N purity. Then, the circular cover 6 equipped with the seed crystals is placed on and thereby seals the cylindrical crucible 1, which is provided with the thermal insulation material 14 on all sides (i.e., above, below, and peripherally around the crucible). After that, the reaction unit together with the thermal insulation material 14 is placed at a predetermined position in the reaction enclosure 15 and is heated with the induction coils 2. For example, the induction coils 2 are RF coils surrounding the reaction enclosure 15 (e.g., a quartz tube) so as to heat the reaction unit. In that case, the temperature at which silicon carbide crystals grow can be controlled by controlling the output power of the RF generator. The reaction unit is heated to 2200° C. while the one or more thermometers 16 above the device monitor the temperature of each seed crystal. The temperature measurements are important reference data during crystal growth and serve to ensure the consistency in both size and quality of the crystals 5 grown.

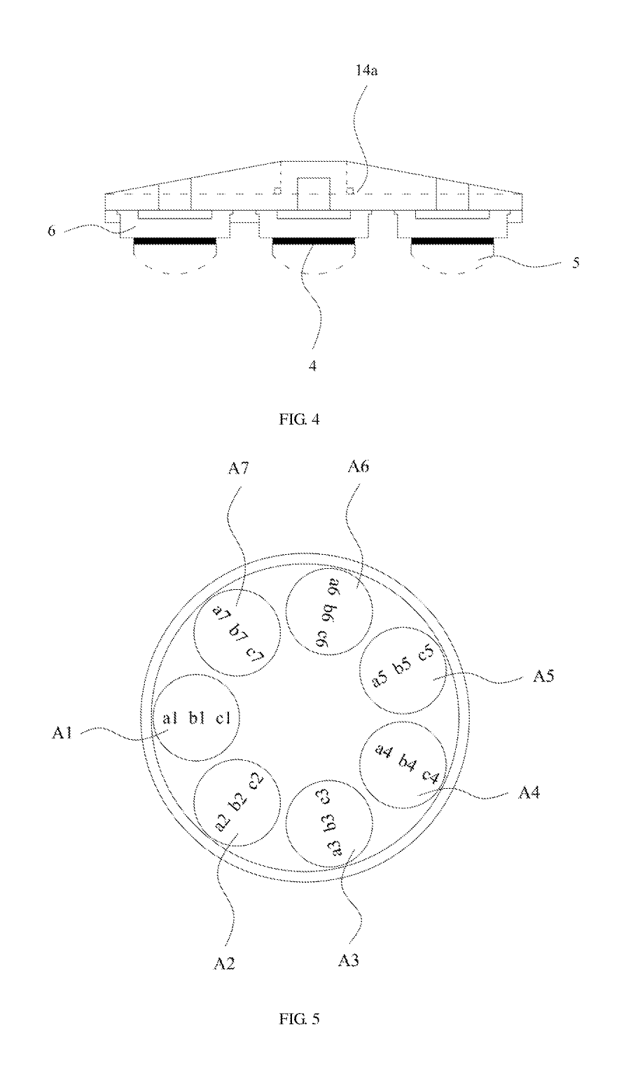

Referring to FIG. 4, in order to create a temperature field in which temperature consistency is achieved between the seven seed crystals A1˜A7 as well as between any two points in each seed crystal, the thermal insulation material 14 covering the circular cover 6 is specially designed to contribute, in conjunction with the rotating mechanism 17, to uniform heating of the seed crystals (4, A1˜A7). More particularly, the thickness of the thermal insulation material 14 on the circular cover 6 is decreased from the center of the cover toward the rim of the cover. This piece of thermal insulation material 14 can be of any configuration as long as the foregoing thickness variation is preserved. For example, the thermal insulation material 14 on the circular cover 6 can be cut into right-angled triangular pieces 14a, with the 90-degree corners facing inward and the 60-degree corners facing upward, as shown in FIG. 4. However, the configuration of the thermal insulation material 14 on the circular cover 6 is by no means limited to the triangular pieces 14a described above.

Apart from using multiple seed crystals for crystal growth, the present embodiment uses the rotating mechanism 17 and the specially shaped thermal insulation material 14 to enable a temperature field in which the temperatures of any two seed crystals and at any two points in each seed crystal are generally the same. Referring to FIG. 5 and taking the seed crystals A1, A3, and A6 for example, if only the rotating mechanism 17 is provided (i.e., without the aforesaid thickness variation of the thermal insulation material 14 on the circular cover 6), the positions a1, a3, and a6 will be of the same temperature (i.e., temperature at a1=temperature at a3=temperature at a6); the positions b1, b3, and b6 will be of the same temperature (i.e., temperature at b1=temperature at b3=temperature at b6); and the positions c1, c3, and c6 will be of the same temperature (i.e., temperature at c1=temperature at c3=temperature at c6). For the seed crystal A1, however, the positions a1, b1, and c1 are of different temperatures (i.e., temperature at a1≠temperature at b1≠temperature at c1); and the same applies to the seed crystals A3, A6, etc.

As the rotating mechanism 17 alone cannot create a uniform temperature field, the thicknesses of the triangular pieces of thermal insulation material 14a are reduced from the center, and along the radial direction, of the circular cover 6 to provide further assistance, as detailed below. With the induction coils 2 surrounding the reaction enclosure 15, the temperature of the circular cover 6 is higher in the peripheral region than in the central region. The thicker portion of each triangular piece of thermal insulation material 14a provides better thermal insulation and therefore allows the corresponding central region of the circular cover 6 to reach a higher temperature. Thus, the present invention successfully creates a uniform temperature field by increasing the thickness of the inner portion of each triangular piece of thermal insulation material 14a. As a result, taking the seed crystals A1, A3, and A6 for example again, the positions a1, b1, and c1 of the seed crystal A1 will be of the same temperature (i.e., temperature at a1=temperature at b1=temperature at c1); the positions a3, b3, and c3 of the seed crystal A3 will be of the same temperature (i.e., temperature at a3=temperature at b3=temperature at c3); and the positions a6, b6, and c6 of the seed crystal A6 will be of the same temperature (i.e., temperature at a6=temperature at b6=temperature at c6). In other words, the rotating mechanism 17 and the specially shaped triangular pieces of thermal insulation material 14a of the present invention can provide temperature consistency between each two seed crystals and between any two points in each seed crystal.

### Embodiment 1

As stated above, crystal growth not only requires high-quality seed crystals and pure raw materials, but also requires the crucible and the thermal insulation material to contain as few impurities as possible. In addition, the reaction enclosure should contain as few impurities as possible so that crystal growth is kept from external contamination. In this embodiment, a mechanical pump and a turbomolecular pump are used in combination but in different stages so as to create a vacuum (with an air pressure of 5×10⁻⁵ torr) in the reaction enclosure 15 (i.e., the quartz tube in this embodiment) and fill the quartz tube with high-purity argon.

A stable atmosphere control system is crucial to the growing process of silicon carbide crystals. The quality of crystal growth can be affected by not only temperature, but also the pressure in the reaction enclosure 15 and the flow of the special gas employed. Therefore, precisely controlling the pressure in the reaction enclosure 15 and the flow of the special gas is important to crystal growth. Typically, a mass flow controller is used to control the gas flow into and out of the reaction enclosure 15. The mass flow controller can work with a pump system capable of air extraction rate adjustment to provide reliable control of gas input and extraction. Simply put, air extraction is carried out by a vacuum pump, and precise atmosphere control, by the mass flow controller so that the special gas flow and reaction pressure in the reaction enclosure can reach those required for crystal growth.

Once the foregoing preparation steps are completed, the crystal growth process can be started. The pressure of the crystal growing environment is set at 100 torr, the average crystal growing speed is kept at 100 μm/hr, and the crystal growing time is 120 hours. During the growing process, the desired impurities can be added as appropriate. For example, nitrogen can be added to produce n-type silicon carbide single crystals.

The results of the crystal growing process in this embodiment are tabulated below. As shown in the table, the device and method of the present invention simultaneously produced seven silicon carbide single crystals in the reaction unit, and the crystals produced are of fairly consistent quality. It is therefore proved that the present invention is indeed capable of overcoming the drawback of the prior art that only one crystal can be grown at a time.

| | | | Crystal | | Height | |
|---|---|---|---|---|---|---|
| | Shape | Initial | height | Peripheral | of | Crystal |
| | of | crystal | at | crystal | crystal | growing |
| | crystal | height | center | height | growth | speed |
| Item | grown | (mm) | (mm) | (mm) | (mm) | (μm/hr) |
| 1^{st} 2″ | Rounded | 22.02 | 34.00 | 28.00 | 11.98 | 99.83 |
| seed | | | | | | |
| crystal | | | | | | |
| 2^{nd} 2″ | Rounded | 22.08 | 33.98 | 27.98 | 11.90 | 99.16 |
| seed | | | | | | |
| crystal | | | | | | |
| 3^{rd} 2″ | Rounded | 22.10 | 34.13 | 28.13 | 12.03 | 100.25 |
| seed | | | | | | |
| crystal | | | | | | |
| 4^{th} 2″ | Rounded | 22.00 | 34.05 | 28.05 | 12.05 | 100.42 |
| seed | | | | | | |
| crystal | | | | | | |
| 5^{th} 2″ | Rounded | 21.98 | 33.94 | 27.94 | 11.96 | 99.67 |
| seed | | | | | | |
| crystal | | | | | | |
| 6^{th} 2″ | Rounded | 21.90 | 33.83 | 27.83 | 11.93 | 99.42 |
| seed | | | | | | |
| crystal | | | | | | |
| 7^{th} 2″ | Rounded | 21.95 | 33.94 | 27.94 | 11.99 | 99.92 |
| seed | | | | | | |
| crystal | | | | | | |

1. A device for simultaneously producing multiple silicon carbide crystals, comprising:
a reaction unit comprising a cylindrical crucible and a circular cover corresponding to the cylindrical crucible;
a thermal insulation material arranged above, below, and peripherally around the reaction unit;
a reaction enclosure surrounding the reaction unit and the thermal insulation material; and
a heating system corresponding to and encircling the reaction enclosure;
wherein the cylindrical crucible has a side provided with a rotating mechanism for driving the cylindrical crucible into rotation, and the thermal insulation material above the reaction unit is arranged on the circular cover and has a thickness decreasing from a center of the circular cover toward a rim of the circular cover.

2. The device of claim 1, wherein the circular cover is fixedly provided with a plurality of silicon carbide seed crystals each having a diameter ranging from 2 to 8 inches.

3. The device of claim 1, wherein the cylindrical crucible and the circular cover are made of a material selected from the group consisting of graphite and tantalum.

4. The device of claim 1, wherein the thermal insulation material is carbon fiber.

5. The device of claim 1, wherein the heating system is a radio-frequency heater or a resistance heater and is configured to heat the reaction unit to 1900° C.˜2500° C.

6. The device of claim 1, further comprising one or a plurality of thermometers provided above the reaction unit.

7. The device of claim 2, wherein the silicon carbide seed crystals have a crystal structure of a 3C, 4H, 6H, 2H, or 15R polytype.

8. The device of claim 1, wherein the reaction enclosure remains a vacuum and is a quartz tube.

9. The device of claim 8, wherein the reaction enclosure further comprises a mass flow controller therein.

10. A method for simultaneously producing multiple silicon carbide single crystals with the device of claim 1, comprising the steps of:
(i) arranging a plurality of silicon carbide seed crystals on the circular cover of the reaction unit, and filling the corresponding cylindrical crucible with a sufficient amount of silicon carbide powder for crystal growth to a predetermined height;
(ii) placing the reaction unit into the reaction enclosure, and extracting air from within the reaction enclosure, in which the reaction unit is placed, so as to maintain a predetermined pressure in the reaction enclosure; and
(iii) heating the reaction unit to 1900° C.˜2500° C. with the heating system such that the silicon carbide powder sublimes and grows multiple silicon carbide single crystals on the silicon carbide seed crystals respectively.
